(19) United States
(12) Patent Application Publication
(10) Pub. No.: US 2022/0029381 A1
(43) Pub. Date: Jan. 27, 2022

(54) LIGHT EMITTING MODULES WITH IRREGULAR AND/OR APERIODIC CONDUCTIVE TRACES

(71) Applicant: ams Sensors Singapore Pte. Ltd., Singapore (SG)

(72) Inventor: Olivier Ripoll, Rüschlikon (CH)

(21) Appl. No.: 17/297,696

(22) PCT Filed: Dec. 9, 2019
(86) PCT No.: PCT/SG2019/050604

§ 371 Date: May 27, 2021

Related U.S. Application Data
(60) Provisional application No. 62/783,638, filed on Dec. 21, 2018.

(51) Int. Cl. H01S 5/042; H01S 5/183; H01S 5/068

(52) U.S. Cl. CPC H01S 5/04256; H01S 5/06825; H01S 5/18305

(57) ABSTRACT

An example system includes an optical element defining a first surface, and a substrate layer defining a second surface and a third surface opposite the second surface. The second surface of the substrate layer is adjacent the first surface the optical element. The system also includes a conductive trace disposed on the third surface of the substrate layer. The optical element is operable to emit light in a first direction through the substrate layer and the conductive trace. The conductive trace defines at least one of an aperiodic path or an irregular path.

### TECHNICAL FIELD

The disclosure relates to light emitting modules.

### BACKGROUND

Electronic devices, such as smart phones, tablets, and other portable computing devices, can include technologies to record three-dimensional images, sense motion and/or gestures. Digital recording methods use various types of miniature illuminators, which interact with cameras to record dynamical events in three-dimensional regions. These illuminators can be of various forms and deliver different types of functions. Some illuminate a wide area with very short pulses for Light Detection and Ranging (LIDAR) type measurements recording time of flight information. Other illuminators are pulsed or continuous wave (CW), and project structured light patterns onto a scene. The digital camera records an image of the structured light pattern, and software algorithms are used to determine three-dimensional scene information from modifications in the patterned image.

One technology that is suitable for miniature illuminators is high power vertical cavity surface emitting laser (VCSEL) devices and array devices. These devices can be pulsed with very fast rise times suitable for time-of-flight applications. They are small, but produce high power laser beams with efficient electro-optic conversion. However, various optical components (e.g., an optical diffuser) can be placed in the beam path to modify the beam properties for the specific application.

The optical output power of a bare VCSEL typically can, in some cases, be so high that it may cause damage to a person's eye or skin in the event the quality of the optical component is compromised. Thus, it is important to ensure that the high power laser illuminators meet laser safety regulations when operated in the portable computing devices. For example, the illuminator may be part of an assembly that, under normal operating conditions, maintains eye-safe operation by preventing a person from getting too close to the illuminator. However, in some cases, damage (e.g., cracks) to the optical structure that modifies the output beam for safe operation, or the presence of moisture or chemical contamination on the optical structure, may result in safety hazards. Likewise, if the optical structure were to fall off or be removed, safety could be compromised.

### SUMMARY

The present disclosure describes illumination modules that facilitate detection of abnormalities that might cause an eye-safety hazard or other risk. In an example implementation, an illumination module includes a light source, one or more light transmissive portions (e.g., optically transparent or translucent components, such as lenses, gratings, light guides, substrate layers, protective layers, etc.). Further, the illumination module includes one or more electrically conductive traces positioned on a surface of the light source and/or one or more of the light transmissive portions. During operation, the illumination module can emit light from the light source, through the light transmissive portions and the electrically conductive traces, and into the surrounding environment. Further, during operation of the light source, the illumination module can induce an electric current through the electrically conductive trace, and monitor the electric current flowing through the electrically conductive trace. Upon detecting certain changes in the electric current (e.g., an interruption of the electric current), the illumination module can determine that the illumination module has been modified (e.g., damaged or compromised). In response, the illumination module can turn off or otherwise regulate (e.g., reduce) its optical power output. Further, the electrically conductive traces can be arranged such that they define one or more particular paths that eliminate or otherwise reduce distortion of the emitted light.

Implementations of the illumination module can provide one or more technical benefits. For example, the illumination module can detect modifications that could result in abnormal operation, and in response, turn off or otherwise regulate its optical power output to reduce injury risks to people in the vicinity. Thus, the illumination module can be operated in a safer manner in a variety of different conditions. Further, the illumination module can emit light with fewer distortions and/or a lesser degree of distortion. Thus, the illumination module can emit light in a more precise manner.

In an aspect, a system includes an optical element defining a first surface, and a substrate layer defining a second surface and a third surface opposite the second surface. The second surface of the substrate layer is adjacent the first surface the optical element. The system also includes a conductive trace disposed on the third surface of the substrate layer. The optical element is operable to emit light in a first direction through the substrate layer and the conductive trace. The conductive trace defines at least one of an aperiodic path or an irregular path.

Implementations of this aspect can include one or more of the following features.

In some implementations, the conductive trace can include two or more first conductive segments. Each of the first conductive segments can be parallel to each of the other first conductive segments. The first conductive segments cab have a common length. At least one of the first conductive segments can have a width that is different from a width of at least one of the other first conductive segments.

In some implementations, the third surface of the substrate layer can include a central region and a peripheral region surrounding the central region. The first conductive segments can be disposed, at least in part, on the central region of the third surface of the substrate layer.

In some implementations, the conductive trace can include two or more first conductive segments. At least two of the first conductive segments can define an oblique angle.

In some implementations, at least one of the first conductive segments can have a length that is different from a length of at least one of the other first conductive segments.

In some implementations, the third surface of the substrate layer can include a central region and a peripheral region surrounding the central region. The first conductive segments can be disposed, at least in part, on the central region of the third surface of the substrate layer.

In some implementations, the conductive trace can define an irregular spiral path.

In some implementations, the conductive trace can include one or more first conductive segments defining a curved path along the third surface of the substrate layer.

In some implementations, the conductive trace can include one or more first conductive segments defining a jagged path along the third surface of the substrate layer. The jagged path can define at least one acute angle.

In some implementations, the conductive trace can include one or more first conductive segments defining one or more Hilbert curves along the third surface of the substrate layer.

In some implementations, the conductive trace can include one or more first conductive segments defining one or more Moore curves along the third surface of the substrate layer.

In some implementations, the system can include a glass layer defining one or more grooves, and an epoxy layer covering at least a portion of the glass layer and disposed in the one or more grooves.

In some implementations, the epoxy layer can have an index of refraction that is substantially similar to an index of refraction of the glass layer.

In some implementations, the optical element can include a vertical-cavity surface-emitting laser (VCSEL) emitter.

In some implementations, the system can further include a current detector electrically coupled to a first end and a second end of the conductive trace. The current detector can be operable to induce a current through the conductive trace, detect an interruption of current through the conductive trace, and responsive to detecting the interruption of current, transmit a fault signal indicating the interruption of current.

In some implementations, the conductive trace can include indium tin oxide (ITO).

The details of one or more implementations are set forth in the accompanying drawings and the description below. Other features and advantages will be apparent from the description and drawings, and from the claims.

### BRIEF DESCRIPTION OF THE DRAWINGS

FIG. 1A is schematic cross-sectional diagram of an example illumination module.

FIG. 2B is a plan view of an illumination module and a path of a conductive trace.

FIGS. 2A-2C show example outputs of light by an illumination module.

FIG. 3 is an image of a cross-section of a substrate layer, a conductive trace, and a protective layer.

FIGS. 4A and 4B show example conductive traces.

FIGS. 5A and 5B show example conductive traces.

FIGS. 6A and 6B show example conductive traces.

FIG. 7 is schematic cross-sectional diagram of another example illumination module.

FIG. 8 is an image of a cross-section of a substrate layer, a conductive trace, a protective layer, and an epoxy layer.

### DETAILED DESCRIPTION

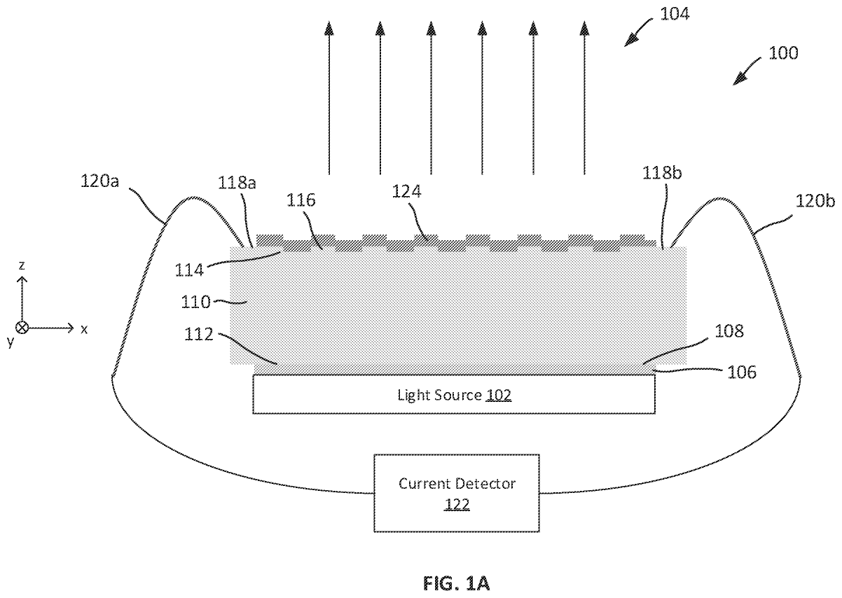

FIG. 1A is a schematic cross-sectional diagram of an example illumination module 100 operable to generate and emit light.

The illumination module 100 includes a light source 102 operable to generate light 104 (e.g., in a z-direction). In some cases, the light source 102 can include one or more lasers, such as e.g., VCSELs or intra-red (IR) lasers. In some cases, the light source 102 can include one or more other devices that generate light, such as light emitting diodes (LEDs), infra-red (IR) LEDs, and organic LEDs (OLEDs).

The illumination module 100 also includes one or more light transmissive optical elements 106 disposed over the light source 102 (e.g., with respect to the z-direction) so as to intersect the path of light 104 generated by the light source 102. The optical elements 106 can include, for example, one or more optical diffusers, lenses, micro-lens arrays, refractive or diffractive optical elements, diffusers, spectral filters, polarizing filters, light guides, and/or some other optical structures operable to modify the optical characteristics of the light 104. In some cases, one or more optical elements 106 can define a planar or substantially planar surface 108 opposite the light source 102 (e.g., a surface along an x-y plane).

The illumination module 100 also includes a light transmissive substrate layer 110 disposed over the one or more optical elements 106 (e.g., with respect to the z-direction). In some cases, the substrate layer 110 can define a first planar or substantially planar surface 112 (e.g., a surface along an x-y plane) adjacent to the surface 108 of the one or more optical elements 106, and a second planar or substantially planar surface 114 (e.g., another surface along an x-y plane) opposite the first surface 112. In some cases, the substrate layer 110 can be composed, at least in part, of SiO₂ or “display” glass, such as Schott D263T-ECO or Borofloat 33, Dow-Corning Eagle 2000.

The illumination module 110 has a light transmissive conductive trace 116 positioned on the surface 114 of the substrate layer 110. The conductive trace 116 defines a path along the substrate 110. FIG. 1B shows a plan view of the illumination module 100 and the path of the conductive trace 116. As shown in FIG. 1B, the conductive trace 116 includes two bond pads 118a and 118b, and several conductive segments 120 defining a path between the bond pads 118a and 118b. In some cases, the conductive trace 116 can extend, at least in part, along a central region of the substrate layer 110 (e.g., a portion of the substrate layer 110 through which the light 104 is transmitted) and/or a peripheral region surrounding the central region. In some cases, the conductive trace 116 can be composed, at least in part, of indium tin oxide (ITO).

The bond pads 118a and 118b are electrically coupled (e.g., via wires or electrically conductive traces 120a and 120b) to a current detector 122. During operation of the illumination module 100 (e.g., while the light source 102 is generating and emitting light 104), the current detector 122 induces a current through the conductive trace 116, and measures the current flowing through the conductive trace 116. Upon detecting certain changes in the electric current (e.g., an interruption of the electric current), the current detector 122 determines that the conductive trace 116 has been modified (e.g., damaged or compromised). This can indicate, for example, that one or more of the components of the illumination module 100 have been damaged or compromised, and that there may be an increased safety risk in continuing the operate the illumination module 100. In response, the current detector can direct the light source 102 to turn off or otherwise regulate (e.g., reduce) its optical power output.

The illumination module 100 also includes a light transmissive protective layer 124 disposed over at least a portion of the conductive trace 116 and the substrate layer 110. In some cases, the protective layer 124 can be composed, at least in part, of glass (e.g., SiO₂).

The light 104 emitted by the light source 102 passes through the one or more optical elements 106, the substrate layer 110, the conductive trace 116, and the protective layer 124. Accordingly, each of these components can potentially affect the path and/or other optical characteristics of the light 104.

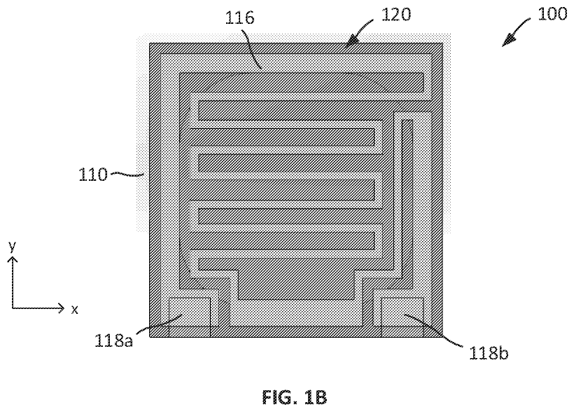

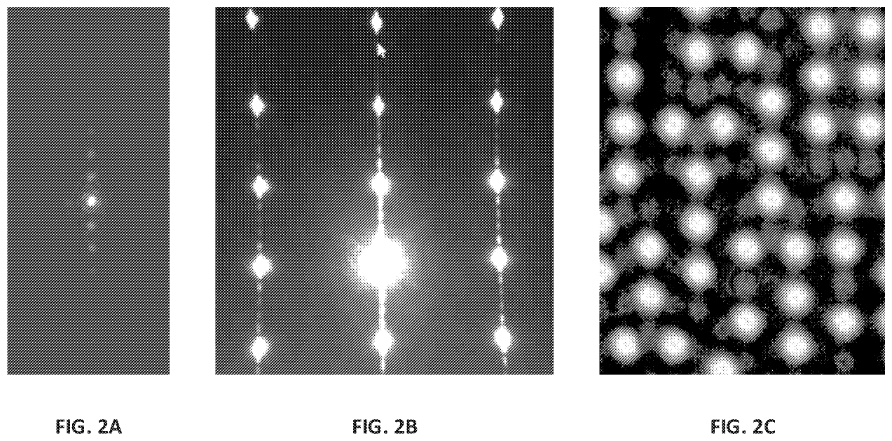

In some cases, a conductive trace 116 having the arrangement shown in FIG. 1B can interfere with the emission of light 104, and can result in parasitic effects. As an example, FIG. 2A shows an example output of light by an illumination module 100 having a single laser light source. Due to interference by the conductive trace, the output includes a primary light dot (e.g., a “signal” dot intended to be emitted by the illumination module), as well as a number of less intense parasitic light dots around the signal light dot.

As another example, FIG. 2B shows an example of light output by an illumination module 100 having a single laser light source and a diffractive optical element (DOE). Due to interference by the conductive trace, the output includes several signal light dots, as well as a number of less intense parasitic light around the signal light dots.

As another example, FIG. 2C shows an example of light output by an illumination module 100 having a several laser light sources and DOEs. Due to interference by the conductive trace, the output includes several signal light dots, as well as a number of less intense parasitic light dots around the signal light dots.

In some cases, these parasitic light dots can increase the background level of noise of the light pattern light emitted by the illumination module, resulting in lower imaging contrast. In some cases, these parasitic light dots can alter the power of the signal dots and degrade the performance of the illumination module.

In general, light may exhibit different optical paths, depending on whether it passes through a conductive trace (e.g., due to differences in the refractive index n of air, e.g., n=1, and the refractive index of conductive trace, e.g., n=1.4 for ITO). In practice, the conductive trace is often protected under a protective glass layer (e.g., as described with respect to FIG. 1A). Accordingly, the difference in refractive index is reduced from 0.4 to 0.05 at the boundary of the substrate/ITO level, reducing artefacts.

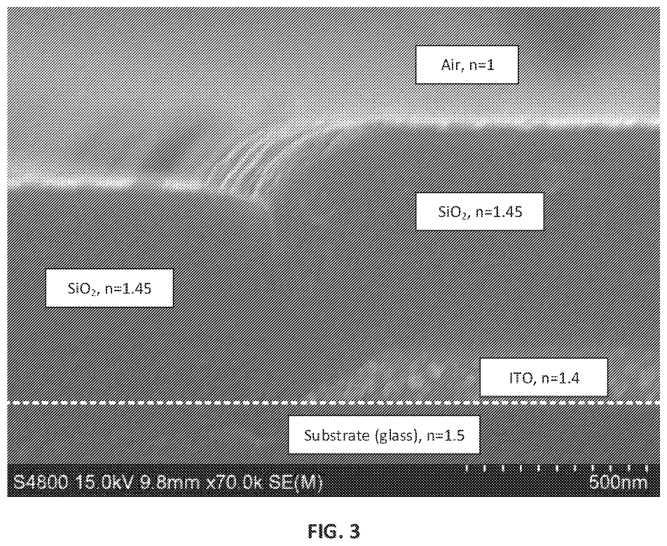

However, the protective glass layer is often deposited according to a constant thickness. Due to the presence of the conductive trace, the glass layer may be higher in some regions (e.g., regions having an underlying conductive trace), and lower in other regions (e.g., regions do not have an underlying conductive trace). As an example, FIG. 3 shows an image of a cross-section of a substrate layer, a conductive trace (e.g., ITO), and a protective layer (e.g., SiO₂). Although the protective layer has a constant thickness, the right region is higher than the left region, as the right region has an underlying conductive trace whereas the left region does not. This uneven height acts as an optical grating, and introduces parasitic effects into the emitted light (e.g., parasitic light dots, as shown in FIGS. 2A-2C).

Various techniques can be used to eliminate or otherwise reduce these parasitic effects. In some cases, instead of using a conductive trace defining a periodic and regular path (e.g., as shown in FIG. 1B), a conductive trace defining an aperiodic and/or an irregular path can be used instead. This can be beneficial, for example, as the resulting diffractive effects of the protective layer would be spread over a larger area (e.g., due to the aperiodicity and/or irregularity of the diffractive structure), rather than concentrated in discrete dots. Accordingly, the parasitic effects are less intense.

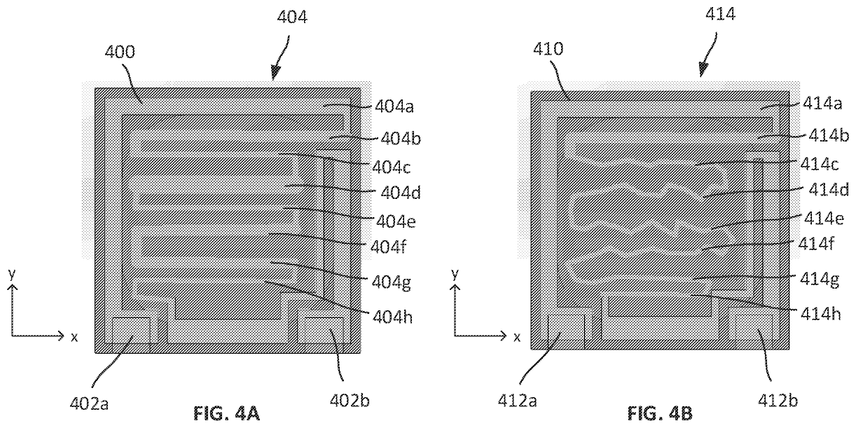

As an example, FIG. 4A shows a conductive trace 400 defining an aperiodic path. The conductive trace 400 includes bond pads 402a and 402b (e.g., to facilitate electrical connection to the current detector 122, and several conductive segments 404 defining a path between the bond pads 402a and 402b). Several of the segments 404 are parallel to one another. For example, the segments 404a-404h extend in the x-direction, and are parallel to one another. Further, several of the segments 404 have a common length. For example, segments 404a and 404b have a common length in the x-direction, and segments 404c-404h have a common length in the x-direction. However, at least some of the segments 404 can have a different width (e.g., in the y-direction) than other segments 404. This aperiodicity in width results in an aperiodic diffractive structure in the protective layer. Accordingly, the parasitic effects are less intense (e.g., compared to those associated with the periodic and regular conductive trace shown in FIG. 1B).

As another example, FIG. 4B shows a conductive trace 410 defining an irregular path. In some cases, an irregular path can exhibit multiple different spatial frequencies along multiple different directions. In some cases, an irregular path have a spatial frequency spectrum that is spread out with respect to several different directions, rather than concentrated along a fewer number of directions. The conductive trace 410 includes bond pads 412a and 412b (e.g., to facilitate electrical connection to the current detector 122, and several conductive segments 414 defining a path between the bond pads 412a and 412b). Several of the segments 414 extend in a common direction, but are not parallel to one another. Rather, they each define a different irregular path. For example, the segments 414a-414h generally extend in the x-direction. However, each of the segments 414a-414h extends along a different irregular path (e.g., not straight across the entire segment). In some cases, one or all of the segments 414 can include define oblique angles (e.g., accurate angles or obtuse angles) relative to one or more segments 404, rather than right angles. This irregularity results in an irregular diffractive structure in the protective layer. Accordingly, the parasitic effects are less intense (e.g., compared to those associated with the periodic and regular conductive trace shown in FIG. 1B).

Although FIGS. 4A and 4B show conductive traces that define either an aperiodic path (e.g., using segments with aperiodic widths) or an irregular path (e.g., using segments with irregular angles and directions), in some cases, conductive traces can define paths that are both aperiodic and irregular. For example, in FIG. 4A, one or more of the segments 404 can extend in irregular directions and/or angles. As another example, in FIG. 4B, one or more of the segments 414 can vary in length and/or width.

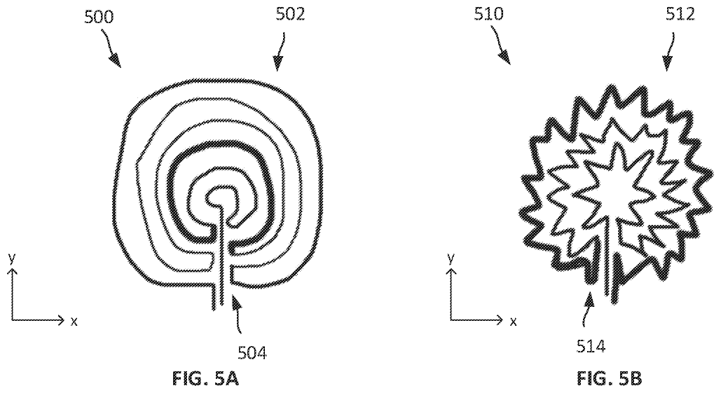

In some cases, a conductive trace can define an aperiodic and/or an irregular spiral. As an example, FIG. 5A shows a conductive trace 500 defining a spiral path (e.g., between two bond pads). For ease of illustration, bond pads have been omitted from FIG. 5A. The conductive trace 500 includes several curved segments 502 that define arcs having successively smaller radii. Further, the conductive traces 500 include several connector segments 504 connecting adjacent curved segments. As the conductive trace 500 defines a path having a range of different angles (e.g., rather than right angles, as shown in FIG. 1B), the resulting diffractive structure in the protective layer spreads parasitic effects over a larger area, rather than concentrating it in discrete locations. Accordingly, the parasitic effects are less intense (e.g., compared to those associated with the periodic and regular conductive trace shown in FIG. 1B).

As another example, FIG. 5B shows a conductive trace 510 defining another spiral path (e.g., between two bond pads). For ease of illustration, bond pads have been omitted from FIG. 5B. The conductive trace 510 includes several jagged segments 512 (e.g., segments defining one or more acute angles) that define jagged arcs having successively smaller radii. Further, the conductive traces 510 include several connector segments 514 connecting adjacent jagged segments. As the conductive trace 510 defines a path having a range of different angles (e.g., rather than right angles, as shown in FIG. 1B), the resulting diffractive structure in the protective layer spreads parasitic effects over a larger area, rather than concentrating it in discrete locations. Accordingly, the parasitic effects are less intense (e.g., compared to those associated with the periodic and regular conductive trace shown in FIG. 1B).

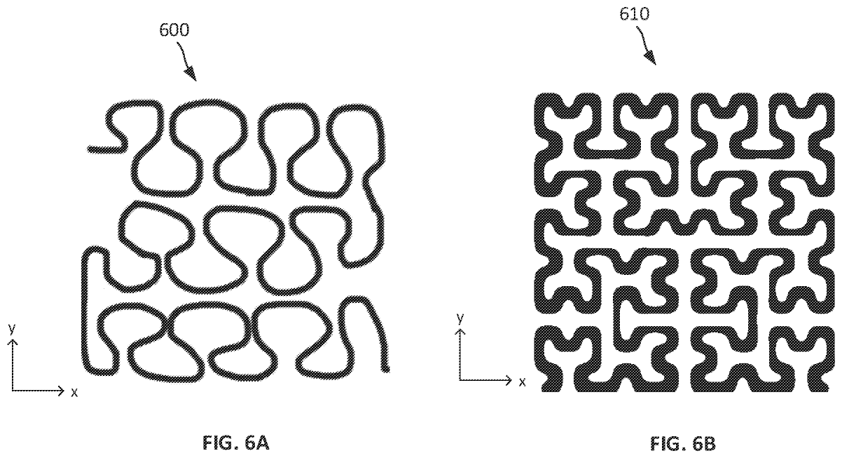

In some cases, a conductive trace can define a curved path. As an example, FIG. 6A shows a conductive trace 600 defining a curved path (e.g., between two bond pads). For ease of illustration, bond pads have been omitted from FIG. 6A. The path of conductive trace 600 includes (or approximates) several iterations of Hilbert curves. As the conductive trace 600 defines a path having a range of different angles (e.g., rather than right angles, as shown in FIG. 1B), the resulting diffractive structure in the protective layer spreads parasitic effects over a larger area, rather than concentrating it in discrete locations. Accordingly, the parasitic effects are less intense (e.g., compared to those associated with the periodic and regular conductive trace shown in FIG. 1B).

As another example, FIG. 6B shows a conductive trace 610 defining another curved path (e.g., between two bond pads). For ease of illustration, bond pads have been omitted from FIG. 6B. The path of conductive trace 610 includes (or approximates) several iterations of Moore curves. As the conductive trace 610 defines a path having a range of different angles (e.g., rather than right angles, as shown in FIG. 1B), the resulting diffractive structure in the protective layer spreads parasitic effects over a larger area, rather than concentrating it in discrete locations. Accordingly, the parasitic effects are less intense (e.g., compared to those associated with the periodic and regular conductive trace shown in FIG. 1B).

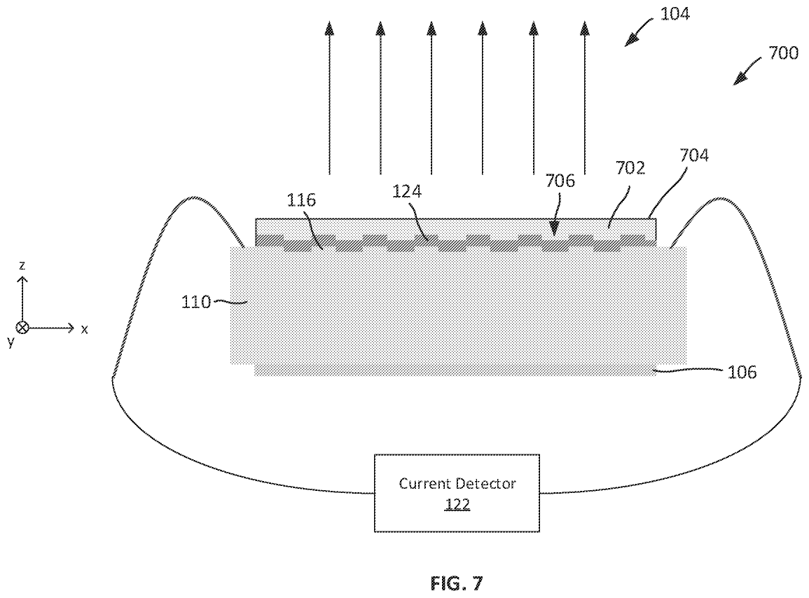

In some cases, parasitic effects can be eliminated or otherwise reduced by applying an epoxy layer over the protective layer. As an example FIG. 7 is a schematic cross-sectional diagram of an example illumination module 700 operable to generate and emit light.

The illumination module 700 can operate in a similar manner as the illumination module 100 described with respect to FIG. 1A. For example, the illumination module 700 can include a light source 102 operable to generate light 104, one or more light transmissive optical elements 106 disposed over the light source 102 so as to intersect the path of light 104 generated by the light source 102, and a light transmissive substrate layer 110 disposed over the one or more optical elements 106. Further, the illumination module 700 can include a light transmissive conductive trace 116 positioned on the surface of the substrate layer 110, and a concurrent detector 122 operable to induce a current through the conductive trace 116, measure the current flowing through the conductive trace 116, and direct the light source 102 to turn off or otherwise regulate its optical power output based on the measured current. Further, the illumination module 700 can include a light transmissive protective layer 124 disposed over at least a portion of the conductive trace 116 and the substrate layer 110.

In this example, the illumination module 700 further includes an epoxy layer 702 disposed over at least a portion of the protective layer 124. In some cases, the epoxy layer 702 can be dispensed and/or spin-coated onto the protective layer 124. The epoxy layer 702 varies in thickness (e.g., with respect to the z-direction), such that it defines a planar or substantially planar exterior surface 704. For example, due to the presence of the conductive trace 116, the protective layer 124 may define one or more grooves 706. The epoxy layer 702 fills in the grooves 706, and defines a new exterior surface 704.

The epoxy layer 702 can have a refractive index that is the same or substantially similar to the refractive index of the protective layer 124. This is beneficial, for example, in eliminating or otherwise reducing the diffractive effects of the protective layer 124 and the grooves 706. In some cases, the epoxy layer 702 can have a refractive index that within n=0.05 of the refractive index of the protective layer 124 (e.g., the epoxy layer 702 can have a refractive index within between 1.4 and 1.5, and the protective layer 124 can have a refractive index of 1.45).

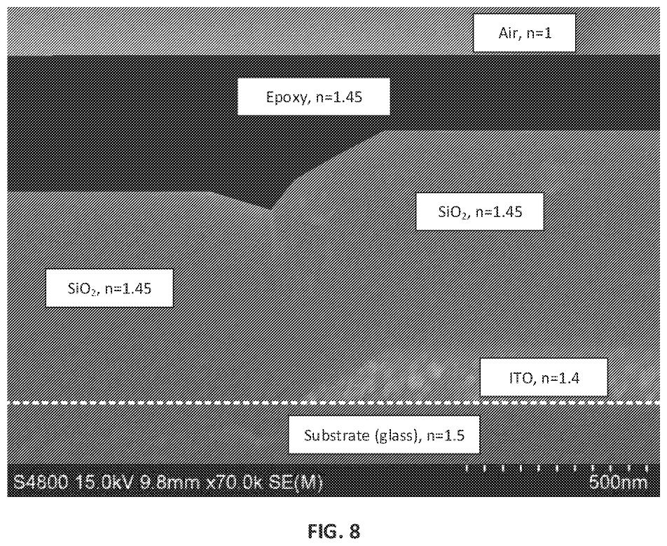

As an example, FIG. 8 shows an image of a cross-section of a substrate layer, a conductive trace (e.g., ITO), a protective layer (e.g., SiO₂), and an epoxy layer. Although the protective layer has a constant thickness, the right region is higher than the left region, as the right region has an underlying conductive trace whereas the left region does not). Typically, this uneven height acts as an optical grating, and introduces parasitic effects into the emitted light (e.g., parasitic light dots, as shown in FIGS. 2A-2C).

However, the epoxy layer is applied such that it defines a planar or generally planar outer surface (e.g., instead of a surface defining one or more grooves that act as an optical grating). Further, the refractive index of the epoxy layer is the same or substantially similar to the refractive index of the protective layer (e.g., approximately n=1.45). Accordingly, the optical path of light is not substantially altered when passing between the protective player and the epoxy. As the epoxy effectively eliminates the effects of the uneven height of the protective layer on the transmitted light, parasitic effects (e.g., parasitic dots) are eliminated or otherwise reduced.

In some cases, an illumination module can include both an epoxy layer (e.g., as described with respect to FIGS. 7 and 8) and a conductive trace defining an aperiodic and/or irregular path (e.g., as described with respect to FIGS. 4A, 4B, 5A, 5B, 6A, and 6B).

A number of embodiments have been described. Nevertheless, various modifications may be made without departing from the spirit and scope of the invention. Accordingly, other embodiments are within the scope of the claims.

1. A system comprising:
an optical element defining a first surface;
a substrate layer defining a second surface, and a third surface opposite the second surface, wherein the second surface of the substrate layer is adjacent the first surface the optical element; and
a conductive trace disposed on the third surface of the substrate layer;
wherein the optical element is operable to emit light in a first direction through the substrate layer and the conductive trace, and
wherein the conductive trace defines at least one of an aperiodic path or an irregular path.

2. The system of claim 1, wherein the conductive trace comprises two or more first conductive segments, wherein each of the first conductive segments is parallel to each of the other first conductive segments, and wherein the first conductive segments have a common length, and
wherein at least one of the first conductive segments has a width that is different from a width of at least one of the other first conductive segments.

3. The system of claim 2, wherein the third surface of the substrate layer comprises a central region and a peripheral region surrounding the central region, and wherein the first conductive segments are disposed, at least in part, on the central region of the third surface of the substrate layer.

4. The system of claim 1, wherein the conductive trace comprises two or more first conductive segments, wherein at least two of the first conductive segments define an oblique angle.

5. The system of claim 4, wherein at least one of the first conductive segments has a length that is different from a length of at least one of the other first conductive segments.

6. The system of claim 4, wherein the third surface of the substrate layer comprises a central region and a peripheral region surrounding the central region, and wherein the first conductive segments are disposed, at least in part, on the central region of the third surface of the substrate layer.

7. The system of claim 1, wherein the conductive trace defines an irregular spiral path.

8. The system of claim 7, wherein the conductive trace comprises one or more first conductive segments defining a curved path along the third surface of the substrate layer.

9. The system of claim 8, wherein the conductive trace comprises one or more first conductive segments defining a jagged path along the third surface of the substrate layer, the jagged path defining at least one acute angle.

10. The system of claim 1, wherein the conductive trace comprises one or more first conductive segments defining one or more Hilbert curves along the third surface of the substrate layer.

11. The system of claim 1, wherein the conductive trace comprises one or more first conductive segments defining one or more Moore curves along the third surface of the substrate layer.

12. The system of claim 1, further comprising a glass layer defining one or more grooves, and
an epoxy layer covering at least a portion of the glass layer and disposed in the one or more grooves.

13. The system of claim 12, wherein the epoxy layer has an index of refraction that is substantially similar to an index of refraction of the glass layer.

14. The system of claim 1, wherein the optical element comprises a vertical-cavity surface-emitting laser (VCSEL) emitter.

15. The system of claim 1, further comprising a current detector electrically coupled to a first end and a second end of the conductive trace,
wherein the current detector is operable to:
induce a current through the conductive trace,
detect an interruption of current through the conductive trace, and
responsive to detecting the interruption of current, transmit a fault signal indicating the interruption of current.

16. The system of claim 1, wherein the conductive trace comprises indium tin oxide (ITO).
